(19) United States
(12) Patent Application Publication
(10) Pub. No.: US 2020/0315062 A1
(43) Pub. Date: Oct. 1, 2020

(54) HEAT TRANSFER MEMBERS IN RECEIVING BAYS

(71) Applicant: HEWLETT PACKARD ENTERPRISE DEVELOPMENT LP, Houston, TX (US)

(72) Inventors: Kevin B. Leigh, Houston, TX (US); Everett R. Salinas, Pasadena, TX (US); John Franz, Houston, TX (US)

(21) Appl. No.: 16/371,956

(22) Filed: Apr. 1, 2019

(51) Int. Cl. H05K 7/20; F28F 9/013

(52) U.S. Cl. CPC H05K 7/20272; F28F 2275/20; F28F 9/013; H05K 7/20645

(57) ABSTRACT

In some examples, a receiving bay includes a first heat transfer member that is moveable along a first axis, and a retainer to restrict movement of the first heat transfer member along a second axis different from the first axis. The first heat transfer member is to contact a second heat transfer member of a device when inserted in the receiving bay, the first heat transfer member moveable along the first axis by the contact with the second heat transfer member as the device is inserted in the receiving bay.

### BACKGROUND

Electronic equipment can include receiving bays to receive electronic devices. Examples of electronic equipment include computer server equipment, communication equipment, or data storage equipment.

### BRIEF DESCRIPTION OF THE DRAWINGS

Some implementations of the present disclosure are described with respect to the following figures.

FIG. 1 is a partial perspective view of receiving bays of a system, according to some examples.

FIG. 2 is a partial perspective view of a receiving bay and an electronic device module inserted in the receiving bay, according to some examples.

FIG. 3 is a perspective view of a guide bracket that includes spring-loaded plungers according to some examples.

FIG. 4 is a perspective view of an assembly including a spring-loaded plunger and a spring, according to some examples.

FIG. 5 is a perspective view of multiple heat transfer members movably attached to the guide bracket using the spring-loaded plungers, according to some examples.

FIG. 6 is a schematic diagram of a receiving bay according to further examples.

FIG. 7 is a schematic diagram of a system according to further examples.

FIG. 8 is a schematic diagram of an electronic equipment according to further examples.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

In the present disclosure, use of the term “a,” “an”, or “the” is intended to include the plural forms as well, unless the context clearly indicates otherwise. Also, the term “includes,” “including,” “comprises,” “comprising,” “have,” or “having” when used in this disclosure specifies the presence of the stated elements, but do not preclude the presence or addition of other elements.

Electronic devices can be inserted into receiving bays of a mounting structure, such as a rack or other similar structure, of electronic equipment. Examples of electronic devices include storage devices, memory devices, communication devices (e.g., signal transceiver devices, etc.), and so forth. During operation, the electronic devices can generate heat that is to be dissipated.

In some cases, liquid cooling can be used to transfer heat away from the electronic devices. In some cases, liquid cooling can result in a complex arrangement of cooling components that can take up valuable space in electronic equipment. If the electronic equipment has a relatively dense arrangement of electronic devices, the space taken up by the cooling components can lead to reduced space for accommodating the electronic devices. Moreover, complex cooling components can be costly, which can drive up the overall cost of the electronic equipment.

In accordance with some implementations of the present disclosure, receiving bays of electronic equipment can include moveable heat transfer members that are thermally coupled to a fluid conduit for carrying a cooling fluid (e.g., a cooling liquid). The moveable heat transfer members can be mounted using biasing members in the respective receiving bays, to allow the moveable heat transfer members to move along a first axis in the receiving bays.

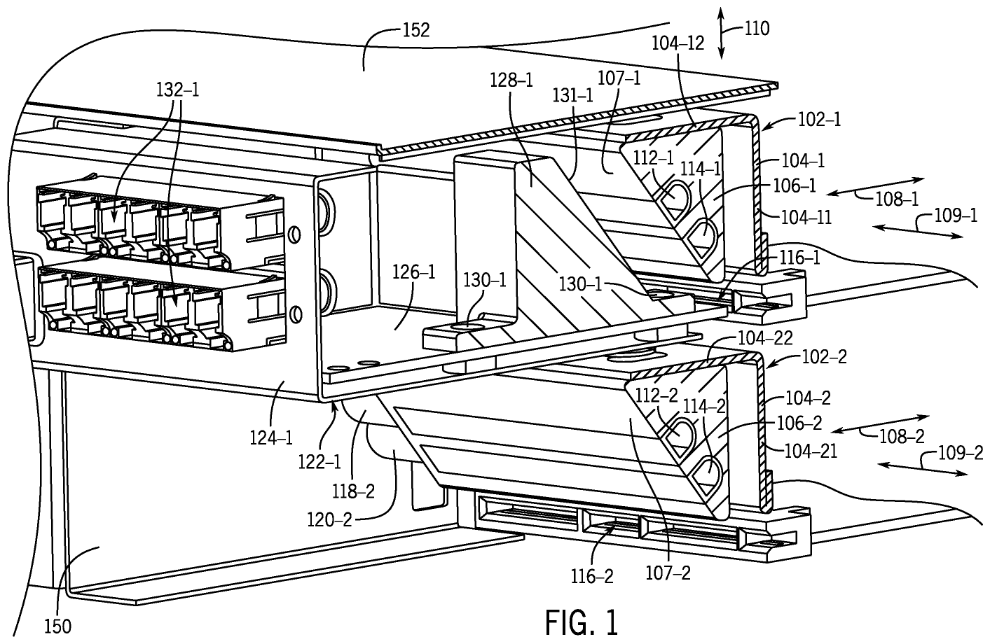

FIG. 1 is a perspective view of receiving bays 102-1 and 102-2 of a mounting structure, such as an enclosure for housing electronic devices. Side-by-side receiving bays are separated by a wall 150. A shelf (not shown) can separate over-under adjacent receiving bays.

The receiving bays 102-1 and 102-2 include respective guide brackets 104-1 and 104-2. The receiving bays 102-1 and 102-2 further include respective floating heat transfer members 106-1 and 106-2 that are moveably attached to the corresponding guide brackets 104-1 and 104-2.

A “heat transfer member” is formed of a thermally conductive material, such as a metal or other thermally conductive material, and is used to transfer heat away from another structure (discussed further below).

Each heat transfer member 106-1 or 106-2 is “floating” in the sense that the heat transfer member is moveable along a first axis that is generally parallel to a direction of insertion or removal of a pluggable electronic device module. In FIG. 1, the floating heat transfer member 106-1 is moveable along the first axis 108-1, and the floating heat transfer member 106-2 is moveable along the first axis 108-2.

As shown in FIG. 1, an electronic device module 122-1 is partially inserted into the receiving bay 102-1. The insertion or removal of the electronic device module 122-1 is generally along the first axis 108-1. A similar electronic device module can be inserted into or removed from the receiving bay 102-2 along the first axis 108-2. An “electronic device module” can refer to an assembly that includes an electronic device, or multiple electronic devices.

Movement of each of the heat transfer members 106-1 and 106-2 is restricted along a second axis 110, which is perpendicular to the first axis 108-1 or 108-2. In the orientation shown in FIG. 1, the second axis 110 is a vertical axis, whereas the first axis 108-1 or 108-2 extends is a first horizontal axis. “Restricting” movement of a heat transfer member along a given axis refers to preventing movement of the heat transfer member along the given axis, or reducing an amount that the heat transfer member can move along the given axis as compared to movement in a different axis.

Additionally, movement of the floating heat transfer member 106-1 is also restricted in a third axis 109-1 that is perpendicular to both the first axis 108-1 and the second axis 110. Similarly, movement of the floating heat transfer member 106-2 is also restricted in a third axis 109-2 that is perpendicular to both the first axis 108-2 and the second axis 110. The third axes 109-1 and 109-2 are second horizontal axes.

Retainers for restricting movement of the floating heat transfer members 106-1 and 106-2 along the axes 110, 109-1, and 109-2 are discussed further below.

The guide bracket 104-1 includes a first guide bracket segment 104-11 and a second guide bracket segment 104-12. The first guide bracket segment 104-11 and the second guide bracket segment 104-12 are generally perpendicular to each other and are integrally connected to one another. In other words, the first and second guide bracket segments 104-11 and 104-12 of the guide bracket 104-1 are formed from a single plate (e.g., a metal plate) or other structure into a generally L-shape or other angled shape.

Each guide bracket 104-1 or 104-2 can be formed of a metal or other materials.

In the example of FIG. 1, the first guide bracket segment 104-11 extends in a direction that is generally parallel to the second axis 110, and the second guide bracket segment 104-12 extends in a direction that is generally parallel to the first axis 108-1.

The guide bracket 104-2 similarly includes a first guide bracket segment 104-21 and a second guide bracket segment 104-22, arranged in similar fashion as the first and second guide bracket segments 104-11 and 104-12 of the guide bracket 104-1.

In accordance with some implementations of the present disclosure, each heat transfer member 106-1 or 106-2 includes liquid conduits. The heat transfer member 106-1 includes a liquid conduits 112-1 and 114-1. Although two liquid conduits are shown, in other examples, a heat transfer member can include a different number (1 or greater than 2) of liquid conduits. The liquid conduits 112-1 and 114-1 can be used to transfer cooling liquid to the heat transfer member 104-1 from a source (not shown) of the cooling liquid (e.g., cooling liquid from source supply lines attached to first ends of the liquid conduits 112-1 and 114-1). Heat may be transferred from the device heat transfer member 128 into the cooling liquid, via the heat transfer member 106 and the walls of the liquid conduits 112-1 and 114-1. The liquid conduits 112-1 and 114-1 carry heated liquid to return lines (not shown) connected to second ends of the liquid conduits 112-1 and 114-1. The return lines can carry the heated liquid to a heat dissipation device, such as a heat exchanger, where the heated liquid can be cooled. The heat dissipation device can then provide the cooling liquid back to the supply lines that feed the first ends of the liquid conduits 112-1 and 114-1.

Each of the liquid conduits 112-1 and 114-1 can be formed of a tube, which can be a tube formed of a metal (e.g., copper, etc.) or another thermally conductive material. In a different example, the liquid conduits 112-1 and 114-1 can be formed as passages through the heat transfer member 104-1. In the illustrated example, the liquid conduits 112-1 and 114-1 have exposed surfaces, which are to make contact with the device heat transfer member 128-1 when the electronic device module 122 is installed in the receiving bay 102-1. In some circumstances, this direct contact between the liquid conduits 112-1 and 114-1 and the device heat transfer member 128 may improve the rate at which heat is transferred from the device heat transfer member 128-1 into the liquid coolant. In some examples, the exposed surfaces of the liquid conduits 112-1 and 114-1 are flush with and parallel to a sloped surface 107-1 of the floating heat transfer member 106-1, so that the exposed surfaces and the sloped surface 107-1 can both make thermal contact with a sloped surface 131-1 of a device heat transfer member 128-1 that is part of an electronic device module 122-1. This may increase the rate of heat transfer by allowing more paths for the heat to flow into the liquid coolant. In some examples (not illustrated), the liquid conduits 112-1 and 114-1 do not have exposed portions and do not contact the device heat transfer member 128-1. The provision of multiple liquid conduits allows for more evenly distributed heat extraction surfaces from the device heat transfer member 122-1. In other examples, one liquid conduit having a large contact surface can be used, or more than two liquid conduits can be used.

The heat transfer member 104-2 similarly includes liquid conduits 112-2 and 114-2.

As further shown in FIG. 1, the liquid conduit 112-2 is connected to a flexible liquid conduit 118-2, and the liquid conduit 114-2 is fluidically connected to a flexible liquid conduit 120-2. The flexible liquid conduit 118-2 is to fluidically connect the liquid conduit 112-2 to another liquid conduit that is part of another heat transfer member (not shown in FIG. 1). Similarly, the flexible liquid conduit 120-2 is to fluidically connect the liquid conduit 114-2 to another liquid conduit of another heat transfer member (not shown in FIG. 1).

Each of the flexible liquid conduits 118-2 and 120-2 is formed of a flexible material, such as plastic or other pliable material. A liquid conduit is considered to be “flexible” if it is capable of bending without breaking, such as due to movement of the floating heat transfer member 106-2 along the first axis 108-2.

In the ensuing discussion, liquid conduits (e.g., 112-1, 114-1, 112-2, 114-2) that are part of respective heat transfer members can be formed of a material that is more rigid than the material of respective flexible liquid conduits. As a result, the liquid conduits that are part of respective heat transfer members are referred to as “rigid” liquid conduits.

Rigid liquid conduits are fluidically interconnected to one another by a flexible liquid conduit. A flexible liquid conduit is to pass cooling liquid between rigid liquid conduits.

Examples of the flexible materials include a fluorinated ethylene propylene (FEP) material, or other flexible material.

Although not shown, the liquid conduits 112-1 and 114-1 of the heat transfer member 106-1 are similarly fluidically connected to flexible liquid conduits.

Rigid liquid conduits are nested into a respective floating heat transfer member and brazed, soldered, or otherwise attached. Once the rigid liquid conduits are installed in the respective floating heat transfer member, the rigid liquid conduits cannot bend as the rigid liquid conduits are resting inside cavities of the respective floating heat transfer member. The flexible liquid tubing in between floating heat transfer members is flexible enough to allow biasing members (e.g., spring-loaded plungers 202 discussed further below) to operate freely and without any binding or restriction, and to allow the heat transfer member to move along its full range of motion without breaking or permanently bending the flexible liquid conduit. Each of the floating heat transfer members is allowed to move independent of its neighboring (or flanking) floating heat transfer member.

In some examples, a liquid conduit can be considered rigid if its modulus of elasticity is greater than 20 gigapascal (GPa), or alternatively, greater than 50 GPa, or alternatively, greater than 75 GPa. For example, copper or a copper alloy has a modulus of elasticity in the range between 90-130 GPa, aluminum or an aluminum alloy has a modulus of elasticity in the range between 60-75 GPa, and so forth.

A liquid conduit can be considered flexible if its modulus of elasticity is less than 20 GPa, or alternatively, less than 10 GPa, or alternatively, less than 5 GPa. For example, FEP has a modulus of elasticity of about 0.34 GPa.

Each receiving bay 102-1 or 102-2 includes a respective communication connector 116-1 or 116-2. In some examples, the communication connector 116-1 or 116-2 can include an electrical connector. In other examples, the communication connector 116-1 or 116-2 can include an optical connector, or both an electrical connector and an optical connector.

In the example of FIG. 1, the receiving bay 106-2 is empty (i.e., an electronic device module is not inserted in the receiving bay 104-2. In contrast, the electronic device module 122-1 is shown as being partially inserted in the receiving bay 104-1.

In the example of FIG. 1, the electronic device module 122-1 includes an outer housing 124-1, which supports various components. For example, a circuit board 126-1 can be mounted to the housing 124-1. The circuit board 126-1 can include an electronic device, or alternatively, multiple electronic devices, such as any or some combination of the following: a processor, a storage device, a memory device, a communication device, and so forth.

The electronic device module 124-1 further includes the device heat transfer member 128-1 that is attached to the circuit board 126-1 using attachment mechanisms 130-1. The attachment mechanisms 130-1 can include a screw or other fastener to attach the device heat transfer member 128-1 to the circuit board 126-1.

The device heat transfer member 128-1 is thermally contacted to an electronic device (or multiple electronic devices) (not visible in FIG. 1) on the circuit board 126-1. The thermal contact can be a direct thermal contact or an indirect thermal contact through a thermal interface layer between the device heat transfer member 128-1 and the electronic device(s).

The device heat transfer member 128-1 has the sloped surface 131-1 that is sloped with respect to the upper surface of the circuit board 126-1 (the upper surface of the circuit board 126-1 is generally parallel to the first axis 108-1 in the example shown). The sloped surface 131-1 of the device heat transfer member 128-1 is to make thermal contact with the complementary sloped surface 107-1 of the floating heat transfer member 106-1 of the receiving bay 104-1. The sloped surface 107-1 is sloped (angled) with respect to the first axis 108-1. The angle of the sloped surface 107-1 or sloped surface 131-1 with respect to the first axis 108-1 does not include a right angle (e.g., 90° or 270°) and does not include a zero angle or a 180° angle, but includes sloped angles (e.g., in a range larger than 0° and less than 90°, or in a range larger than 90° and less than 180°, or in a range larger than 180° or less than 270°, or in a range larger than 270° and less than 360°). In some examples, the sloped angles are in a range between 10° and 80°, or in a range between 100° and 170°, or in a range between 190° and 260°, or in a range between 280° and 350°.

Providing sloped surfaces 107-1 and 131-1 on the respective heat transfer members 106-1 and 128-1 increases the surface area of heat contact between the heat transfer members 106-1 and 128-1, as compared to an example where the surface 107-1 and the surface 131-1 are each perpendicular to the first axis 108-1. The increased contact area between the device heat transfer member 128-1 and a floating heat transfer member 106-1 allows for a larger heat transfer rate, to allow for increased heat dissipation capacity. In addition, the floating nature of the floating heat transfer member 106-1 (that is moveable along the first axis 108-1 in response to insertion of the electronic device module 122-1) allows for a reliable thermal contact to be made between the device heat transfer member 128-1 and the floating heat transfer member 106-1.

The floating heat transfer member 106-2 similarly has a sloped surface 107-2 that is sloped (angled) with respect to the first axis 108-2.

Thermally engaging the device heat transfer member 128-1 with the floating heat transfer member 106-1 allows for a “dry connection” between the electronic device module 122-1 and the receiving bay 102-1. In other words, thermal engagement can be accomplished between the electronic device module 122-1 and the receiving bay 102-1 without the use of a connection at which liquid is exchanged between the electronic device module 122-1 and the receiving bay 102-1. In some examples, the floating heat transfer member 106-1 may also allow for a connection that is free of a thermal-interface-material (TIM), such as a thermal paste or thermal grease. This ability to avoid using a TIM may be beneficial, for example, in applications in which the electronic device module 122-1 may be expected to be inserted in and removed from the receiving bay 102-1 multiple times, as a TIM may need to be reapplied every time the electronic device module 122-1 is inserted into the bay 102.

Once the electronic device module 122-1 is fully inserted in the receiving bay 102-1, the device heat transfer member 128-1 is thermally engaged with the floating heat transfer member 106-1, which allows for heat generated by the electronic device(s) in thermal contact with the device heat transfer member 128-1 to be dissipated to the floating heat transfer member 106-1. The heat transferred from the device heat transfer member 128-1 to the floating heat transfer member 106-1 can then be carried away by cooling liquid in the liquid conduit 112-1.

As the electronic device module 122-1 is inserted into the receiving bay 104-1, a mating communication connector (e.g., an edge connector) of the electronic device module 122-1 (which is communicatively connected to the circuit board 126-1) makes a connection (electrical and/or optical connection) with the communication connector 116-1.

After the device and floating heat transfer members and the communication connectors are engaged due to the electronic device module 122-1 being fully inserted in place, a device latch (not shown) may be used to maintain positive mating pressure between the heat transfer members and the communication connectors.

As further shown in FIG. 1, the example electronic device module 122-1 includes various optical connectors 132-1, which can accept external optical cables to make optical connections with other devices (not shown).

FIG. 1 also shows a cover plate 152 above the receiving bay 102-1. The cover plate 152 can be part of the chassis structure, such as a switch system.

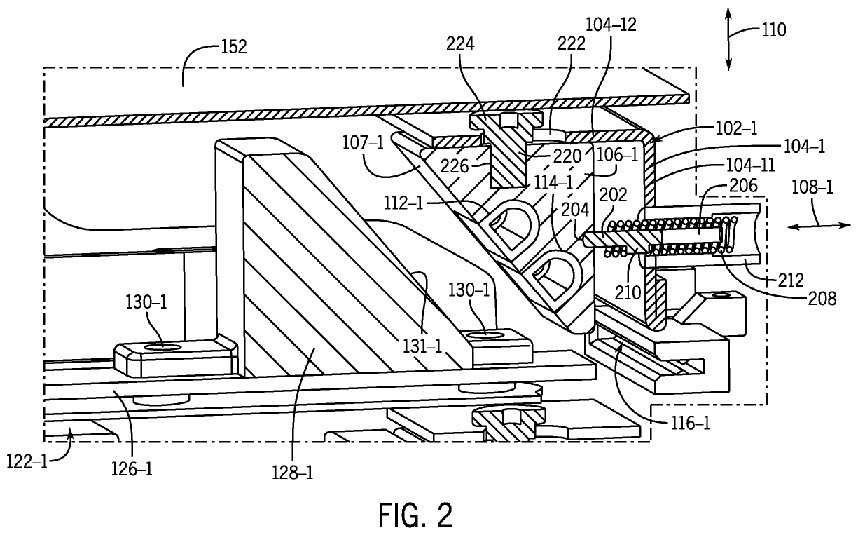

FIG. 2 is a different perspective view that shows the receiving bay 102-1 and the electronic device module 122-1 received partially in the receiving bay 102-1. FIG. 2 shows a spring-loaded plunger 202 that engages a dimple 204 in a rear surface of the floating heat transfer member 106-1. In other examples, instead of the plunger 202 and the dimple 204, other types of engagement members can be employed.

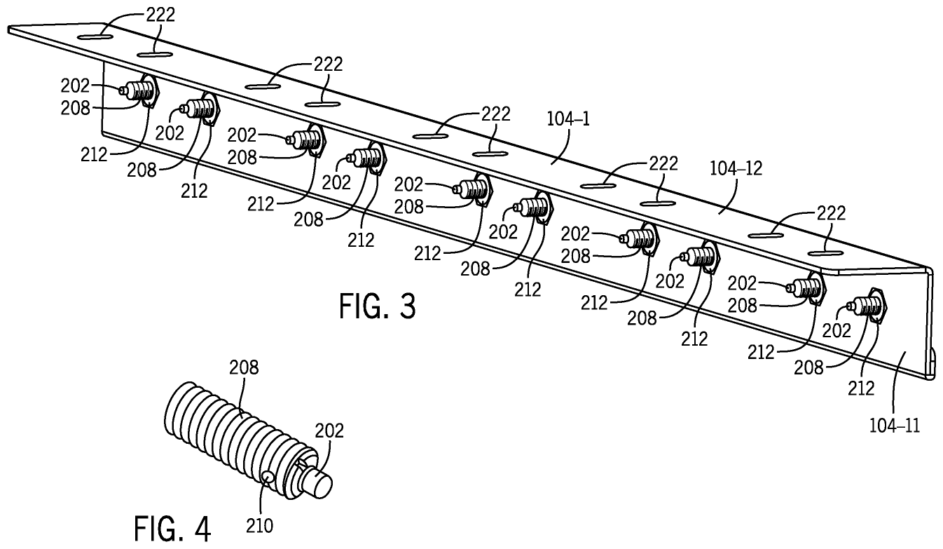

The spring-loaded plunger 202 is partially received in an inner bore 206 of a spring 208. A thread lock 210 of the spring-loaded plunger 202 protrudes into an opening of the spring 208 to prevent the spring-loaded plunger 202 from losing its last position inside the inner bore 206 of the spring 208 over time as a result of use. In examples where multiple (e.g., a pair of) spring-loaded plungers 202 are engaged to each floating heat transfer member (such as shown in FIG. 3), the thread locks 210 for the multiple spring-loaded plungers 202 can tune the spring-loaded plungers 202 such that they apply an even and generally equal load to the floating heat transfer member. The load is determined by how far a spring-loaded plunger 202 protrudes towards the floating heat transfer member.

A portion of the spring 208 is housed in a retention housing 212 that is attached to the first receiving bay segment 104-11. The retention housing 212 maintains the spring 208 in a fixed position relative to the first receiving bay segment 104-11.

In response to a force applied against the floating heat transfer member 106-1 by engagement of the device heat transfer member 128-1 when the electronic device module 122-1 is inserted into the receiving bay 102-1, the spring 208 is compressed such that the spring-loaded plunger 202 and the floating heat transfer member 106-1 engaged to the spring-loaded plunger 202 can move in a direction of the axis 108-1.

The engagement of the spring-loaded plunger 202 with the dimple 204 in the floating heat transfer member 106-1 allows for the floating heat transfer member 106-1 to be moveable along the first axis 108-1.

The force applied by the spring 208 through the spring-loaded plunger 202 against the rear surface of the floating heat transfer member 106-1 allows a biasing force to be applied against the floating heat transfer member 106-1 when the device heat transfer member 128-1 is engaged to the floating heat transfer member 106-1. The biasing force applied by the spring-loaded plunger 202 allows for more reliable thermal contact between the device heat transfer member 128-1 and the floating heat transfer member 106-1.

The assembly of the spring-loaded plunger 202 and the spring 208 is an example of a biasing member to apply a resisting force against the rear surface of the floating heat transfer member 106-1 when the floating heat transfer member 106-1 moves along the first axis 108-1 in response to an opposing force applied against the floating heat transfer member 106-1 by the device heat transfer member 128-1.

In other examples, other types of biasing members can be used.

In some examples, the spring-loaded plunger 202 restricts movement of the floating heat transfer member 106-1 along the second axis 110 and the third axis 109-1 (FIG. 1).

FIG. 2 also shows a shoulder screw 220 (or other type of attachment member for restricting movement in a given direction) that is inserted through an elongated opening 222 of the second guide bracket segment 104-12. The shoulder screw 220 has an enlarged head 224. A lower surface of the enlarged head 224 is spaced apart from an upper surface of the second guide bracket segment 104-12 such that a gap is formed between the lower surface of the enlarged head 224 and the upper surface of the second guide bracket segment 104-12. The shoulder screw 220 can be threadably engaged into a hole 226 of the floating heat transfer member 106-1, to engage the shoulder screw 220 with the floating heat transfer member 106-1. The gap allows the floating heat transfer member 106-1 to freely slide within the boundary of the elongated opening 222.

In addition to the second guide bracket segment 104-12, the shoulder screw 220 with the enlarged head 224 that extends through the elongated opening 222 also aids in restricting movement of the floating heat transfer member 106-1 along the second axis 110. The shoulder screw 220 also restricts movement of the floating heat transfer member 106-1 along the third axis 109-1.

The elongated opening 222 in the second guide bracket segment 104-12 allows for motion of the floating heat transfer member 106-1 along the first axis 108-1.

FIG. 3 is a perspective view of the guide bracket 104-1 that shows a number of spring-loaded plungers 202 attached (by respective springs 208 and retention housings 212 along the length of the guide bracket 104-1. In some examples, a pair of the spring-loaded plungers 202 is used to engage a respective floating heat transfer member (e.g., 106-1). In other examples, a different number (1 or greater than 2) of spring-loaded plungers 202 can be used to engage respective floating heat transfer members.

Elongated openings 222 are provided through the second guide bracket segment 104-12. Shoulder screws 220 as shown in FIG. 2 can extend through respective elongated openings 222 to engage corresponding floating heat transfer members.

FIG. 4 illustrates an example plunger assembly including the spring-loaded plunger 202 and spring 208.

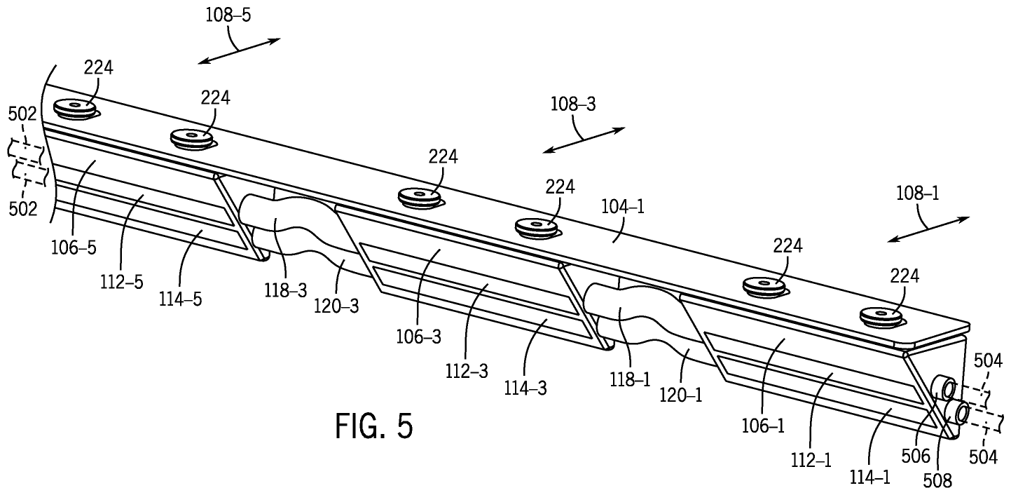

FIG. 5 is a perspective view that shows multiple floating heat transfer members 106-1, 106-3, and 106-5 attached to the guide bracket 104-1. The floating heat transfer members 106-1, 106-3, and 106-5 are independently moveable along respective first axes 108-1, 108-3, and 108-5. In other words, each floating heat transfer member 106-1, 106-3, or 106-5 is moveable along the respective first axis 108-1, 108-3, 108-5 without moving any of the other floating heat transfer members.

In the example of FIG. 5, it is shown that a pair of shoulder screws (heads 224 of the shoulder screws visible in FIG. 5) are attached to each respective floating heat transfer member. In other examples, a different number of shoulder screws can be used to attach to each respective floating heat transfer member.

As further shown in FIG. 5, the flexible liquid conduit 118-1 fluidically connects a rigid liquid conduit 112-3 and the rigid liquid conduit 112-1. The flexible liquid conduit 120-1 fluidically connects a rigid liquid conduit 114-3 and the rigid liquid conduit 114-1.

Similarly, the flexible liquid conduit 118-3 fluidically connects a rigid liquid conduit 112-5 and the rigid liquid conduit 112-3, and a flexible liquid conduit 120-3 fluidically connects a rigid liquid conduit 114-5 and the rigid liquid conduit 114-3.

As further shown in FIG. 5, supply lines 502 (for supplying cooling liquid) are connected to left ends of the left-most (in the view of FIG. 5) rigid liquid conduits (e.g., 112-5, 114-5 or additional rigid liquid conduits to the left of 112-5, 114-5 in FIG. 5). Return lines 504 (for receiving heated liquid) are coupled to right ends 506 and 508 of respective rigid liquid conduits 112-1, 114-1 (in the view of FIG. 5). Cooling liquid flows from left to right (in the view of FIG. 5) from the supply lines 502 to the return lines 504.

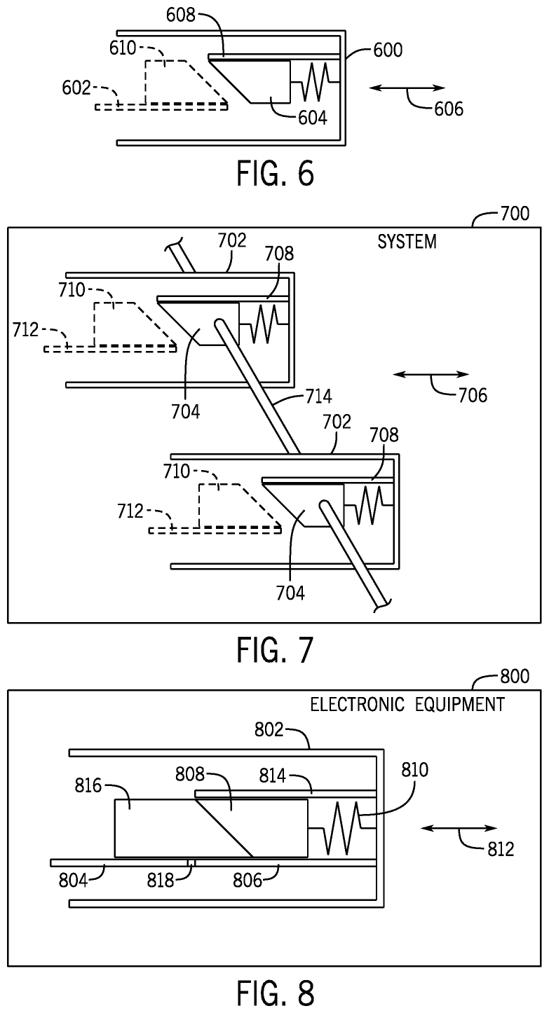

FIG. 6 is a block diagram of a receiving bay 600 to receive a device 602 according to some examples. The receiving bay 600 includes a first heat transfer member 604 (e.g., a floating heat transfer member discussed above) that is moveable along a first axis 606 (e.g., 108-1 or 108-2).

The receiving bay 600 further includes a retainer 608 (e.g., the second guide bracket portion 104-12 or 104-22, the combination of the spring-loaded plunger 202 and the dimple 204, the shoulder screw 220, etc.) to restrict movement of the first heat transfer member along a second axis (e.g., 110 or 109-1 or 109-2) different from the first axis 606.

The first heat transfer member 604 is to contact a second heat transfer member 610 of the device 602 when inserted in the receiving bay 600, the first heat transfer member 604 moveable along the first axis 606 by the contact with the second heat transfer member 610 as the device 602 is inserted in the receiving bay 600.

FIG. 7 is a block diagram of a system 700 according to some examples. The system 700 includes a plurality of receiving bays 702. Each respective receiving bay 702 includes a first heat transfer member 704 that is moveable along a first axis 706, and a retainer 708 to restrict movement of the first heat transfer member along a second axis different from the first axis 706.

The first heat transfer member 704 is to contact a second heat transfer member 710 of a device 712 when inserted in the receiving bay 702. The first heat transfer member 704 is moveable along the first axis 706 by the contact with the second heat transfer member 710 as the device is inserted in the receiving bay 702.

A liquid conduit 714 carries cooling fluid to the first heat transfer members 704 of the plurality of receiving bays 700.

FIG. 8 is a block diagram of an electronic equipment 800 according to some examples. The electronic equipment 800 may be one of servers, communication devices, storage devices, or other electronic devices, for example.

The electronic equipment 800 includes a receiving bay 802 to receive an electronic device module 804. The receiving bay 802 includes a communication connector 806. The receiving bay 802 further includes a first heat transfer member 808 movably mounted in the receiving bay using a biasing member 810, the first heat transfer member 808 moveable along a first axis 812.

The receiving bay 802 further includes a retainer 814 to restrict movement of the first heat transfer member 808 along a second axis different from the first axis 812.

The electronic device module 804 received in the receiving bay 802 includes a second heat transfer member 816 to thermally contact the first heat transfer member 808 when the electronic device module 804 is inserted in the receiving bay 802. The first heat transfer member 808 is moveable along the first axis 810 by the contact with the second heat transfer member 816 as the electronic device module 804 is inserted in the receiving bay 802. The electronic device module 804 includes a complementary communication connector 818 to mate with the communication connector 806 of the receiving bay 802 when the electronic device module 804 is inserted in the receiving bay 802.

In the foregoing description, numerous details are set forth to provide an understanding of the subject disclosed herein. However, implementations may be practiced without some of these details. Other implementations may include modifications and variations from the details discussed above. It is intended that the appended claims cover such modifications and variations.

What is claimed is:

1. A receiving bay comprising:
a first heat transfer member that is moveable along a first axis; and
a retainer to restrict movement of the first heat transfer member along a second axis different from the first axis,
wherein the first heat transfer member is to contact a second heat transfer member of a device when inserted in the receiving bay, the first heat transfer member moveable along the first axis by the contact with the second heat transfer member as the device is inserted in the receiving bay.

2. The receiving bay of claim 1, further comprising a biasing member to apply a resisting force against the first heat transfer member when the first heat transfer member moves along the first axis.

3. The receiving bay of claim 2, wherein the biasing member comprises a spring.

4. The receiving bay of claim 2, further comprising a bracket, the biasing member attached to the bracket, and the surface being a surface of the bracket.

5. The receiving bay of claim 4, wherein the retainer comprises a first portion of the bracket that is angled with respect to a second portion of the bracket, the surface being part of the second portion.

6. The receiving bay of claim 5, wherein the second portion comprises an opening, and the receiving bay further comprises:
an attachment member attached to the first heat transfer member through the opening, the attachment member allowing movement of the first heat transfer member along the first axis and restricting movement of the first heat transfer member along a third axis different from the first and second axes.

7. The receiving bay of claim 2, wherein the first heat transfer member has a first engagement member, and the biasing member has a second engagement member engaged to the first engagement member, wherein the first and second engagement members are to restrict movement of the first heat transfer member in the second axis and in a third axis different from the first and second axes.

8. The receiving bay of claim 7, wherein the first engagement member comprises a dimple, and the second engagement member engages the dimple.

9. The receiving bay of claim 1, further comprising a liquid conduit contacted to the first heat transfer member, the liquid conduit to carry a cooling liquid to transfer heat away from the first heat transfer member.

10. The receiving bay of claim 1, wherein the first heat transfer member has a sloped surface to contact a complementary sloped surface of the second heat transfer member, wherein the sloped surface of the first heat transfer member is sloped with respect to the first axis.

11. The receiving bay of claim 1, further comprising a communication connector to connect to a corresponding communication connector of the device.

12. A system comprising:
a plurality of receiving bays, wherein each respective receiving bay of the plurality of receiving bays comprises:
a first heat transfer member that is moveable along a first axis, and
a retainer to restrict movement of the first heat transfer member along a second axis different from the first axis,
wherein the first heat transfer member is to contact a second heat transfer member of a device when inserted in the receiving bay, the first heat transfer member moveable along the first axis by the contact with the second heat transfer member as the device is inserted in the receiving bay; and
a liquid conduit to carry cooling fluid to the first heat transfer members of the plurality of receiving bays.

13. The system of claim 12, wherein the liquid conduit comprises a flexible portion between fluid conduit portions in contact with respective first heat transfer members, the flexible portion to enable movement of a first heat transfer member along the first axis.

14. The system of claim 12, wherein the first heat transfer member has a sloped surface to contact a complementary sloped surface of the second heat transfer member, wherein the sloped surface of the first heat transfer member is sloped with respect to the first axis.

15. The system of claim 12, further comprising:
a guide bracket;
a plurality of plungers attached to the guide bracket, the first heat transfer members attached to the plurality of plungers, each plunger of the plurality of plungers to apply a biasing force against a respective first heat transfer member.

16. The system of claim 15, further comprising:
attachment members attached to the first heat transfer members and the guide bracket, the attachment members to restrict movement of the first heat transfer members along a third axis different from the first and second axes.

17. The system of claim 16, wherein the guide bracket comprises openings through which the attachment members are attached to the first heat transfer members, the attachment members moveable along the openings to allow movement of the first heat transfer members along the first axis.

18. The system of claim 15, wherein the plurality of plungers are engaged to respective dimples on the first heat transfer members.

19. An electronic equipment comprising:
a receiving bay comprising:
a communication connector,
a first heat transfer member movably mounted in the receiving bay using a biasing member, the first heat transfer member moveable along a first axis, and
a retainer to restrict movement of the first heat transfer member along a second axis different from the first axis; and
an electronic device module received in the receiving bay and comprising:
a second heat transfer member to thermally contact the first heat transfer member when the electronic device module is inserted in the receiving bay, the first heat transfer member moveable along the first axis by the contact with the second heat transfer member as the electronic device module is inserted in the receiving bay, and
a complementary communication connector to mate with the communication connector of the receiving bay when the electronic device module is inserted in the receiving bay.

20. The electronic equipment of claim 19, further comprising:
a liquid conduit thermally contacted to the first heat transfer member, the liquid conduit to carry cooling liquid.
